(19) United States
(12) Patent Application Publication
(10) Pub. No.: US 2006/0105578 A1
(43) Pub. Date: May 18, 2006

(54) HIGH-SELECTIVITY ETCHING PROCESS

(76) Inventors: SHIH-PING HONG, HSINCHU (TW); CHIAHUA HO, HSINCHU (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,477

(22) Filed: Nov. 12, 2004

(51) Int. Cl. H01L 21/302

(52) U.S. Cl. 438/723; 438/689; 438/717; 438/738

(57) ABSTRACT

The present invention provides a high-selectivity etching process for fabricating openings for a contact structure or a dual damascene structure in combination with a Si-rich silicon oxynitride (SiON) barrier layer. The process of this invention is suitable for forming at least an opening for a dual damascene opening or a contact opening, and can be applied in a dual damascene structure, a contact plug, a borderless contact structure or a self aligned contact (SAC) structure.

### BACKGROUND OF THE INVENTION

1. Field of Invention

The present invention relates to an etching process for manufacturing semiconductor devices. More particularly, the present invention relates to a high-selectivity etching process for forming openings for a contact structure or a dual damascene structure.

2. Description of Related Art

During the integrated circuit fabrication processes, lithography and etching processes are frequently repeated for transferring patterns with features for a number of layers of different materials formed sequentially on the wafer. After entering the era of ULSI manufacturing, the etching process becomes more significant for fabricating features with sub-half-micron dimensions. In general, etching can be characterized by the selectivity and degree of anisotropy. Etching can be either physical or chemical, or a combination of both. Wet chemical etching results in isotropic etching, while in dry etching, the wafer is bombarded with a highly selective gaseous chemical that anisotropically dissolves exposed surface materials. Dry chemical etching combines the advantages of physical and wet chemical etching in that it is both highly anisotropic and highly selective.

The etch selectivity is defined as the etch rate of the target material relative to (divided by) the etch rate of a reference material. As the integration of semiconductor devices keeps increasing, the etch selectivity becomes an important issue because poor etch selectivity leads to loss of pattern fidelity and line-width control. However, the high (large) aspect ratio, due to a small line-width or a deep via hole in the dual damascene structure, or a deep contact opening, can cause difficulties in etching and result in reduced contact area between via plug and the metal line. In IC fabrication, especially etching for forming high-aspect-ratio openings for contact structures or dual damascene structure, higher selectivity is most desirable.

### SUMMARY OF THE INVENTION

The present invention provides a high-selectivity etching process for fabricating openings for a contact structure or a dual damascene structure in combination with a Si-rich silicon oxynitride (SiON) barrier layer. The process of this invention is suitable for forming at least an opening for a dual damascene opening or a contact opening, and can be applied in a dual damascene structure, a contact plug, a borderless contact structure or a self aligned contact (SAC) structure.

This invention provides a silicon oxide etch process that has a high selectivity of silicon oxide to Si-rich SiON. Also, this invention provides a Si-rich SiON etch process that has a high selectivity of Si-rich silicon oxynitride to silicon oxide. In the etching processes, the Si-rich SiON layer can serve as both an anti-reflective coating (ARC) and an etch barrier layer (hard mask and/or stop layer).

Due to the high etch selectivity of the etching processes, a wider etch process window can be afforded. Also, this Si-Rich SiON layer allows a wider photo latitude during the photolithography step, because this Si-Rich SiON layer has superior light absorption qualities (acting as an ARC layer).

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1B are cross-sectional views showing the process steps in fabricating a contact opening according to the first preferred embodiment of this invention.

FIGS. 2A through 2C are cross-sectional views showing the process steps in fabricating a dual damascene structure according to the second preferred embodiment of this invention.

FIGS. 3A through 3C are cross-sectional views showing the process steps in fabricating a contact opening for a borderless contact structure according to the third preferred embodiment of this invention.

FIGS. 4A through 4C are cross-sectional views showing the process steps in fabricating a self-aligned contact opening according to the fourth preferred embodiment of this invention.

### DESCRIPTION OF THE PREFERRED EMBODIMENTS

The present invention provides at least a high-selectivity etching process used for fabricating openings for a contact structure or a dual damascene structure in combination with a Si-rich silicon oxynitride (SiON) barrier layer. The process of this invention is suitable for forming at least an opening for a dual damascene opening or a contact opening, and can be applied in a dual damascene structure, a contact plug, a borderless contact structure or a self aligned contact (SAC) structure.

The following embodiments provides further descriptions for forming different structures by using at least a highly selective etching process in combination with a Si-rich SiON barrier layer.

In general, the SiON layer can be formed by plasma enhanced chemical vapor deposition (PECVD), using gaseous mixtures including at least silane (SiH₄) and N₂O. By changing the deposition parameters and/or the gaseous sources, characteristics and composition of the SiON layer can be varied.

The silicon-rich SiON layer applied in the present invention preferably is formed according to the following conditions.

Si-rich SiON Deposition Conditions in CVD Chamber

| Parameter | Low limit | Target | High limit |
|---|---|---|---|
| Pressure (torr) | 4 | 5.5 | 7 |
| Power (watts) | 100 | 120 | 150 |
| SiH4 (sccm) | 160 | 207 | 250 |
| N2O (sccm) | 80 | 96 | 125 |
| He (sccm) | 1500 | 1900 | 2500 |
| Temperature ( [symbol] ) | 300 | 400 | 450 |

However, the deposition conditions are not limited to the above range, and the composition of the Si-rich SiON layer can be adjusted according to the requirements of the etching process for higher selectivity.

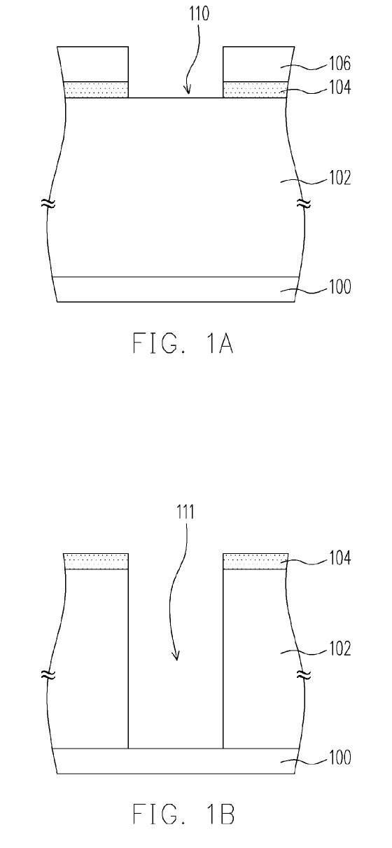

FIGS. 1A through 1B are cross-sectional views showing the process steps in fabricating a contact opening according to the first preferred embodiment of this invention.

Referring to FIG. 1A, a substrate 100 is provided, containing a semiconductor device (not shown) within the substrate 100. A dielectric layer 102 is formed over the substrate 100. The dielectric layer 102 is a silicon oxide layer, for example. A silicon-rich SiON layer 104 is formed on the dielectric layer 102. The silicon-rich SiON layer 104 can act as an anti-reflection coating layer as well as a hard mask layer. Preferably, the silicon-rich SiON layer 104 has a thickness of about 300-1000 Angstroms. A patterned photoresist layer 106 is then formed on the silicon-rich SiON layer 104. Using the patterned photoresist layer 106 as an etching mask, the exposed silicon-rich SiON layer 104 is removed and at least an opening 110 is formed in the silicon-rich SiON layer 104, thus exposing the underlying dielectric layer 102. Next, as shown in FIG. 1B, a dry etching process is performed to remove the exposed dielectric layer 102 and a contact opening 111 is formed in the dielectric layer 102, exposing the substrate 100. Preferably, the dry etching process is an oxide etching process with high selectivity of silicon oxide to silicon oxynitride (SiOx/SiON). The selectivity of silicon oxide to silicon oxynitride (SiOx/SiON) is at least 20 or larger. Preferably, the selectivity of silicon oxide to silicon oxynitride (SiOx/SiON) is equivalent to 100 or even larger. That is, the etching rate of silicon oxide is preferably 100 times (or more) faster than that of Si-rich SiON.

In accordance with the Si-rich SiON layer described above, the exemplary parameters of the oxide etching process with high selectivity of silicon oxide to silicon oxynitride (SiOx/SiON) can be detailed in the following table 1.

TABLE 1
Oxide etching conditions in oxide etcher

| | Lower | | Higher |
|---|---|---|---|
| Parameter | limit | Target | limit |
| Pressure (mtorr) | 40 | 55 | 70 |
| Power (watts) | 800 | 1400 | 1800 |
| Bias Power (watts) | 800 | 1400 | 1800 |
| C₄F₆ (sccm) | 6 | 11 | 18 |
| Ar (sccm) | 100 | 300 | 500 |
| O₂ (sccm) | 0 | 10 | 20 |

| | |
|---|---|
| Etch selectivity | Ranging from about 20 to |
| (oxide/Si-rich SiON) | more than 100 |

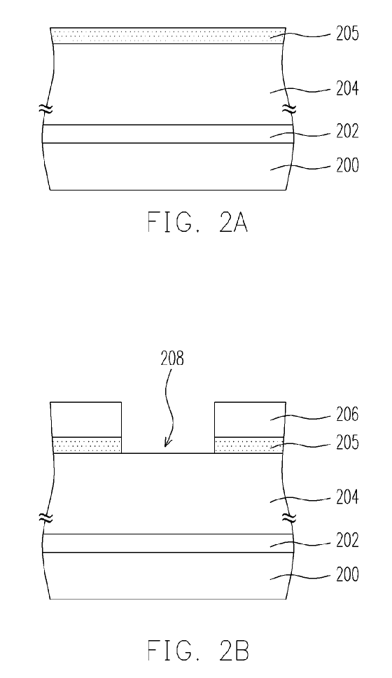

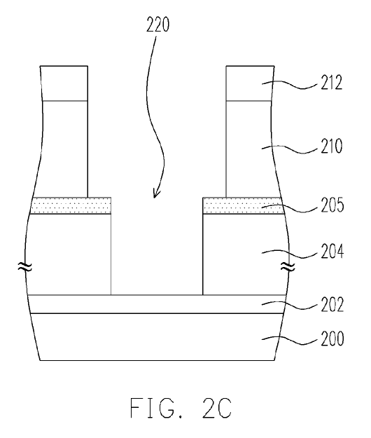

FIGS. 2A through 2C are cross-sectional views showing the process steps in fabricating a dual damascene structure according to the second preferred embodiment of this invention.

First, as shown in FIG. 2A, a substrate 200 having a conductive region or a conductive layer 202 thereon is provided. Next, a first dielectric layer 204 is formed over the substrate 200 and then planarized. The planarized first dielectric layer 204 has a thickness equal to that of a via hole in a final dual damascene structure. An etching stop layer 205 is formed on the first dielectric layer 204. The etching stop layer 205 is a Si-rich SiON layer having a thickness of about 300-500 Angstroms, for example. Meanwhile, the etching stop layer can also be used as an anti-reflection layer.

As shown in FIG. 2B, a patterned first photoresist layer 206 is formed on the Si-rich SiON layer 205. In the subsequent step, using the patterned photoresist layer 206 as a mask, the Si-rich SiON layer 205 is patterned and an opening 208 is formed in the Si-rich SiON layer 205 exposing the underlying first dielectric layer 204. The opening 208 is formed where the via hole is desired.

Next, as shown in FIG. 2C, after removing the remaining first photoresist layer 206, a planarized second dielectric layer 210 and a patterned second photoresist layer 212 are sequentially formed over the substrate 200. Thickness of the second dielectric layer 210 has to be the same as that of the second metal layer (metal line) in the dual damascene structure. Typically, the dielectric layers 204 and 210 may be silicon oxide layers formed by, for example, chemical vapor deposition. The method of planarizing the dielectric layers includes, for example, a chemical-mechanical polishing method.

Then, using the patterned photoresist layer 212 as a mask and the Si-rich SiON layer 205 as the etch stop layer, a dry etching process is performed to remove the exposed dielectric layers 204/210 and a dual damascene opening 220 is formed in the dielectric layers 204/210, exposing the conductive region or layer 202. Preferably, the dry etching process is an oxide etching process with high selectivity of silicon oxide to silicon oxynitride (SiOx/SiON). The selectivity of silicon oxide to silicon oxynitride (SiOx/SiON) is at least 20 or larger. Preferably, the selectivity of silicon oxide to silicon oxynitride (SiOx/SiON) is equivalent to 100 or even larger. That is, the etching rate of silicon oxide is preferably 100 times (or more) faster than that of Si-rich SiON.

By using the oxide etching process with high selectivity of SiOx/SiON, the second dielectric layer 210 is etched to form a trench 220b with the patterned photoresist layer 212 as the mask and etching stops at the etch stop layer 205, while the first dielectric layer 204 is etched to form a via opening 220a using the patterned etch stop layer 205 as an etch mask. Hence, the trench 220b and the via opening 220a together form a dual damascene opening 220 for a dual damascene structure.

Therefore, using a single etching process (i.e. the oxide etching process with high selectivity of SiOx/SiON), the dielectric layers 204/210 are patterned and a portion of the dielectric layers is removed to form an opening 220 for the final dual damascene structure.

The oxide etching process with high selectivity of SiOx/SiON can also be used in combination of a Si-rich SiON etching process with high selectivity of SiON/SiOx for forming a borderless contact structure or self-aligned contact structure.

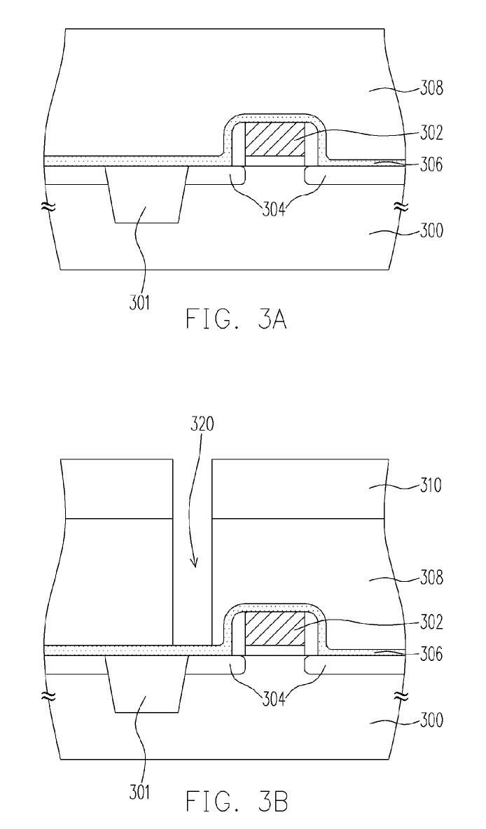

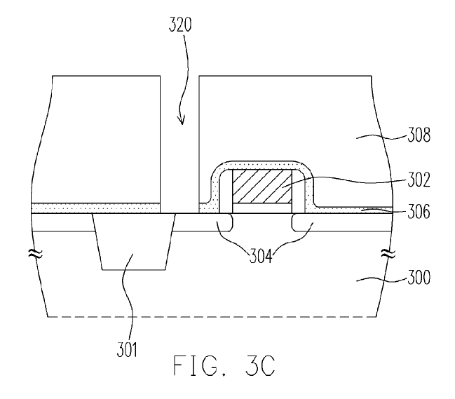

FIGS. 3A through 3C are cross-sectional views showing the process steps in fabricating a contact opening for a borderless contact structure according to the third preferred embodiment of this invention.

First, as shown in FIG. 3A, a substrate 300 having a gate structure 302, conductive regions 304 aside of the gate structure 302, and at least an isolation structure 301 is provided. Next, a Si-rich SiON layer 306 is formed over the substrate 300, covering the gate structure 302, conductive regions 304 and the isolation structure 301. Then a dielectric layer 308 is formed over the substrate 300 and on the Si-rich SiON layer 306. The Si-rich SiON layer 306 has a thickness of about 100-500 Angstroms, for example. For example, the dielectric layer 308 is a silicon oxide layer, formed by, for example, chemical vapor deposition.

As shown in FIG. 3B, a patterned photoresist layer 310 is formed on the dielectric layer 308. In the subsequent step, using the patterned photoresist layer 310 as a mask, the dielectric layer 308 is etched by the oxide etching process with high selectivity of SiOx/SiON, so as to form an opening 320 in the dielectric layer 308, exposing the underlying Si-rich SiON layer 306. The opening 320 is a contact opening and is formed where a contact is desired. Due to the high selectivity of SiOx/SiON of the oxide etching process, etching stops when reaching the Si-rich SiON layer. That is, the Si-rich SiON layer acts as an etching stop layer during the oxide etching process.

Next, as shown in FIG. 3C, a Si-rich SiON etching process with high selectivity of SiON/SiOx is performed to remove the Si-rich SiON layer 306 that is exposed by the opening 320, so that the underlying conductive region 304 is exposed. The exposed conductive region 304 can be connected to the subsequently formed contact (not shown) in the contact opening 320.

The selectivity of silicon oxynitride to silicon oxide (SiON/SiOx) is at least 10 or larger. Preferably, the selectivity of silicon oxynitride to silicon oxide (SiON/SiOx) is about 100 or even larger. That is, the etching rate of Si-rich silicon oxynitride is preferably 100 times (or more) faster than that of silicon oxide.

By using the high selectivity Si-rich SiON etching process, a portion of the Si-rich SiON layer 306 can be removed without damaging the conductive region 304 or the nearby isolation structure 301.

In accordance with the Si-rich SiON layer described above, the exemplary parameters of the Si-rich SiON etching process with high selectivity of silicon oxynitride to silicon oxide to (SiON/SiOx) can be detailed in the following table 2.

TABLE 2
Si-rich SiON etching conditions in silicon etcher

| | Lower | | Higher |
|---|---|---|---|
| Parameter | limit | Target | limit |
| Pressure (mtorr) | 2 | 70 | 100 |
| Power (watts) | 200 | 400 | 1000 |
| Bias Power (watts) | 0 | 80 | 250 |
| HBr (sccm) | 80 | 160 | 240 |
| Cl₂ (sccm) | 0 | 25 | 50 |
| He—O₂ (sccm) | 0 | 5 | 15 |
| N₂ (sccm) | 0 | 3 | 5 |

| | |
|---|---|
| Etch selectivity | Ranging from about 10 to |
| (Si-rich SiON/oxide) | more than 100 |

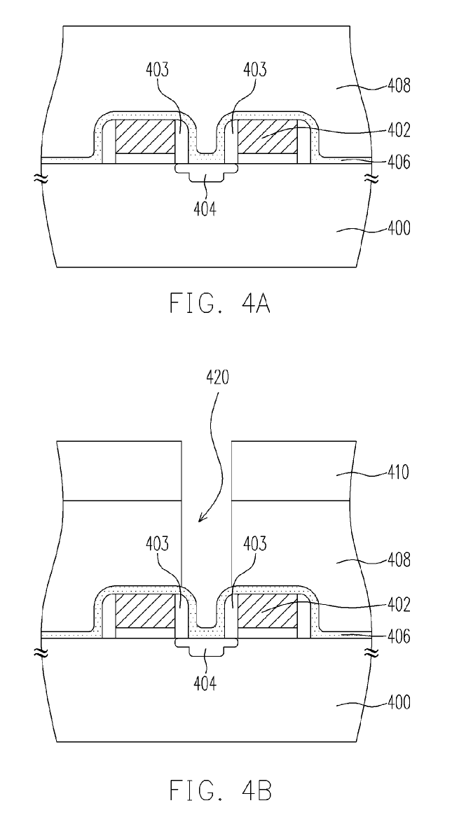

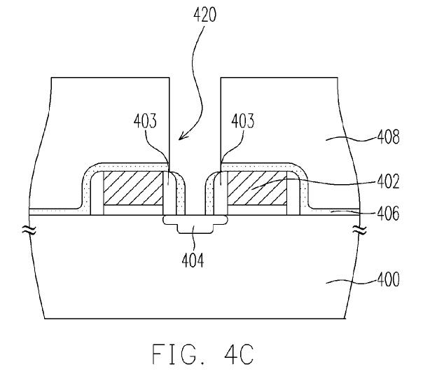

FIGS. 4A through 4C are cross-sectional views showing the process steps in fabricating a self-aligned contact opening according to the fourth preferred embodiment of this invention.

First, as shown in FIG. 4A, a substrate 400 having at least two gate structures 402 and at least a conductive region 404 between the gate structures 402 is provided. The gate structure 402 includes spacers 403 formed on sidewalls of the gate structures 402. Next, a Si-rich SiON layer 406 is formed over the substrate 400, covering the gate structures 402 (and the spacers 403), and the conductive region 404. Then a dielectric layer 408 is formed over the substrate 400 and covers the Si-rich SiON layer 406. The Si-rich SiON layer 406 has a thickness of about 100-500 Angstroms, for example. The dielectric layer 408 is, for example, a silicon oxide layer formed by chemical vapor deposition. The material of the spacers 403 can be silicon dioxide, for example.

As shown in FIG. 4B, a patterned photoresist layer 410 is formed on the dielectric layer 408. In the subsequent step, using the patterned photoresist layer 410 as a mask, the dielectric layer 408 is etched by the oxide etching process with high selectivity of SiOx/SiON, so as to form an opening 420 in the dielectric layer 408, exposing the underlying Si-rich SiON layer 406. The opening 420 is a contact opening and is formed where a contact is desired. Due to the high selectivity of SiOx/SiON of the oxide etching process, etching stops when reaching the Si-rich SiON layer. That is, the Si-rich SiON layer acts as an etching stop layer during the oxide etching process.

Next, as shown in FIG. 4C, a Si-rich SiON etching process with high selectivity of SiON/SiOx is performed to remove the Si-rich SiON layer 406 that is exposed by the opening 420, so that the underlying conductive region 404 is exposed. The exposed conductive region 404 can be connected to the subsequently formed contact (not shown) in the contact opening 420. Since the material of the spacers 403 is silicon dioxide, the Si-rich SiON etching process with high selectivity of SiON/SiOx removes substantially the Si-rich SiON layer 406 without damaging the underlying oxide spacers 403. Hence, the contact opening 420 is formed in a self-aligned way. During the Si-rich SiON etching process, it is not necessary to completely remove the Si-rich SiON layer 406 that is exposed by the opening 420, but only a portion of the Si-rich SiON layer 406 exposed by the opening 420 is removed until the conductive region 404 is exposed.

The selectivity of silicon oxynitride to silicon oxide (SiON/SiOx) is at least 10 or larger. Preferably, the selectivity of silicon oxynitride to silicon oxide (SiON/SiOx) is about 100 or even larger. That is, the etching rate of Si-rich silicon oxynitride is preferably 100 times (or more) faster than that of silicon oxide.

By using the high selectivity Si-rich SiON etching process, a portion of the Si-rich SiON layer 406 can be removed almost without damaging the nearby underlying oxide spacers 403. Moreover, since the Si-rich SiON material of the etch stop layer is non-conductive, the Si-rich SiON layer can be deposited as a blanket layer without shorting concerns.

Hence, the present invention provides a silicon oxide etch process that has a high selectivity of silicon oxide to Si-rich SiON. Also, the present invention provides a Si-rich SiON etch process that has a high selectivity of Si-rich SiON to oxide. These etch processes of the present invention provides high etch selectivity and can be used to form openings for contact structures and dual damascene structures.

The Si-rich SiON layer used in combination of these etch processes can serve as an etch barrier layer (either a hard mask and/or an etch stop layer). Furthermore, based on etch selectivity of the etch barrier layer relative to the dielectric layer, the depth of the formed opening in the dielectric layer can be precisely controlled. Through using the Si-rich SiON layer, the resolution for photolithography is improved because the Si-rich SiON layer can also act as an ARC layer. Furthermore, the etching processes of this invention in combination with the Si-rich SiON layer can provide wider process window for etching, which is especially useful in forming high aspect ratio openings.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A high-selectivity silicon oxide etching process, applicable for a substrate having at least a silicon oxide layer and a patterned silicon-rich silicon oxynitride layer thereon, the process comprising:
providing a gas source consisting essentially of C₄F₆, Ar and O₂;
etching the silicon oxide layer using the patterned silicon-rich silicon oxynitride layer as a mask layer, wherein a selectivity of silicon oxide to Si-rich silicon oxynitride is at least about 20 or larger.

2. The process of claim 1, wherein a pressure of the high selectivity silicon oxide etching process ranges from about 40-70 mtorr, a power of the high-selectivity silicon oxide etching process ranges from about 800-1800 watts, and a bias power of the high selectivity silicon oxide etching process ranges from about 800-1800 watts.

3. The process of claim 2, wherein a flow rate of C₄F₆ ranges from about 6-18 sccm.

4. The process of claim 2, wherein a flow rate of Ar ranges from about 100-500 sccm.

5. The process of claim 2, wherein a flow rate of O₂ ranges from about 0-20 sccm.

6. The process as claimed in claim 2, wherein the selectivity of silicon oxide to silicon-rich silicon oxynitride is about 100 or even larger.

7. The process as claimed in claim 1, wherein the Si-rich silicon oxynitride layer is formed by plasma enhanced chemical vapor deposition (PECVD).

8. A high-selectivity silicon oxynitride etching process, applicable for a substrate having at least a silicon-rich silicon oxynitride layer and a silicon oxide layer underlying the silicon-rich silicon oxynitride layer, the process comprising:
providing a gas source consisting essentially of HBr, Cl₂, N₂ and He—O₂;
etching the silicon rich silicon oxynitride layer without substantially removing the underlying silicon oxide layer, wherein a selectivity of Si-rich silicon oxynitride to silicon oxide is at least about 10 or larger.

9. The process of claim 8, wherein a pressure of the high-selectivity silicon oxynitride etching process ranges from about 2-100 mtorr, a power of the high selectivity silicon oxide etching process ranges from about 200-1000 watts, and a bias power of the high selectivity silicon oxide etching process ranges from about 0-250 watts.

10. The process of claim 9, wherein a flow rate of HBr ranges from about 80-240 sccm.

11. The process of claim 9, wherein a flow rate of Cl₂ ranges from about 0-50 sccm.

12. The process of claim 9, wherein a flow rate of He—O₂ ranges from about 0-15 sccm.

13. The process of claim 9, wherein a flow rate of N₂ ranges from about 0-5 sccm.

14. The process as claimed in claim 9, wherein the selectivity of silicon-rich silicon oxynitride to silicon oxide is about 100 or even larger.

15. The process as claimed in claim 8, wherein the Si-rich silicon oxynitride layer is formed by plasma enhanced chemical vapor deposition (PECVD).

16. A two-staged etching process, applicable for a substrate having at least a silicon oxide structure over the substrate, a silicon-rich silicon oxynitride layer over the silicon oxide structure and a silicon oxide layer on the silicon-rich silicon oxynitride layer, the two-staged process comprising:
performing a first-staged silicon oxide etching process by providing a first gas source consisting essentially of C₄F₆, Ar and O₂;
etching the silicon oxide layer using the silicon-rich silicon oxynitride layer as an etching stop layer, wherein a selectivity of silicon oxide to Si-rich silicon oxynitride is at least about 20 or larger;
performing a second-staged silicon oxynitride etching process by providing a second gas source consisting essentially of HBr, Cl₂, N₂ and He—O₂;
etching the silicon-rich silicon oxynitride layer without substantially removing the underlying silicon oxide structure, wherein a selectivity of Si-rich silicon oxynitride to silicon oxide is at least about 10 or larger.

17. The process of claim 16, wherein a pressure of the silicon oxide etching process ranges from about 40-70 mtorr, a power of the high selectivity silicon oxide etching process ranges from about 800-1800 watts, and a bias power of the high selectivity silicon oxide etching process range from about 800-1800 watts, while flow rates of C₄F₆, Ar and O₂ ranges from about 6-18 sccm, 100-500 sccm and 0-20 sccm respectively.

18. The process as claimed in claim 17, wherein the selectivity of silicon oxide to silicon-rich silicon oxynitride is about 100 or even larger.

19. The process of claim 16, wherein a pressure of the silicon oxynitride etching process ranges from about 2-100 mtorr, a power of the high selectivity silicon oxide etching process ranges from about 200-1000 watts, and a bias power of the high selectivity silicon oxide etching process ranges from about 0-250 watts, while flow rates of HBr, Cl₂, He—O₂, N₂ range from about 80-240 sccm, 0-50 sccm, 0-15 sccm and 0-5 sccm respectively.

20. The process as claimed in claim 19, wherein the selectivity of silicon-rich silicon oxynitride to silicon oxide is about 100 or even larger.
